(19) United States
(12) Patent Application Publication
(10) Pub. No.: US 2020/0335430 A1
(43) Pub. Date: Oct. 22, 2020

(54) Semiconductor Component and Method for Producing Semiconductor Components

(71) Applicant: OSRAM OLED GMBH, Regensburg (DE)

(72) Inventor: Michael Mueller, Garching (DE)

(21) Appl. No.: 16/755,826

(22) PCT Filed: Oct. 11, 2018
(86) PCT No.: PCT/EP2018/077800

§ 371 Date: Apr. 13, 2020

(30) Foreign Application Priority Data
Oct. 13, 2017 (DE) 10 2017 123 898.0

(51) Int. Cl. H01L 23/495; H01L 23/31; H01L 21/56

(52) U.S. Cl. CPC H01L 23/49551; H01L 21/561; H01L 23/4951; H01L 23/3107

(57) ABSTRACT

A semiconductor component and a method for producing semiconductor components are disclosed. In an embodiment a semiconductor component includes at least one semiconductor chip, a front side of the semiconductor component and a rear side of the semiconductor component opposite the front side, a lead frame having a first connection part and a second connection part and a molded body mechanically connecting the first connection part and the second connection part to one another, wherein the first connection part and the second connection part do not project or do not project substantially beyond the molded body in a plan view of the front side, and wherein the first connection part and the second connection part are respectively accessible for external electrical contacting of the semiconductor component at the front side and at the rear side.

This patent application is a national phase filing under section 371 of PCT/EP2018/077800, filed Oct. 11, 2018, which claims the priority of German patent application 10 2017 123 898.0, filed Oct. 13, 2017, each of which is incorporated herein by reference in its entirety.

### TECHNICAL FIELD

The present application relates to a semiconductor component and to a method for producing semiconductor components.

### BACKGROUND

In the case of semiconductor components, for example for use in sensor technology, particularly compact designs are increasingly required, both with regard to the base area and to the component height perpendicular to the base area. In addition, different types of attachment of the components are required for different applications.

### SUMMARY OF THE INVENTION

Embodiments provide a semiconductor component which is distinguished by a compact design and can be used in many ways. Further embodiments provide a method with which semiconductor components can be produced in a compact form in a simple and reliable manner.

Embodiments relate to a semiconductor component, for example, an optoelectronic semiconductor component, which is provided for generating and/or receiving radiation.

The semiconductor component extends in a vertical direction between a front side and a rear side opposite the front side. In particular, the front side and the rear side extend in parallel to one another at least in places. In the lateral direction, the semiconductor component is delimited by side faces which connect the front side and the rear side to one another. The side faces extend in particular perpendicularly or essentially perpendicularly to the front side and/or to the rear side.

The semiconductor component has at least one semiconductor chip. For example, the semiconductor chip is provided for generating and/or for receiving electromagnetic radiation, for example in the visible, ultraviolet or infrared spectral range. For example, the semiconductor chip is an optoelectronic semiconductor chip, for example, a luminescence diode semiconductor chip, such as a light-emitting diode or a laser diode or a photodiode or a phototransistor.

According to at least one embodiment of the semiconductor component, the semiconductor component has a lead frame with a first connection part and a second connection part. The lead frame is in particular self-supporting. For example, the lead frame is formed from a metal sheet during production, wherein the metal sheet may be provided with a coating on one or both sides.

The first connection part and the second connection part are provided in particular for external electrical contacting of the semiconductor component.

According to at least one embodiment of the semiconductor component, the semiconductor component has a molded body. The molded body contains, for example, a plastic material, for example, an epoxy or a silicone. The molded body is molded in particular onto the lead frame. At the points at which the molded body is molded onto the lead frame, the molded body adjoins the lead frame directly. In particular, the molded body mechanically connects the first connection part and the second connection part to one another. The molded body is expediently designed to be electrically insulating.

According to at least one embodiment of the semiconductor component, the first connection part and the second connection part do not project or do not project substantially beyond the molded body in a lateral direction in a plan view of a front side of the semiconductor component. In this context, “not substantially” means in particular that the connection parts each protrude from the molded body in the lateral direction by at most 10 μm.

In particular, an outside face of the first connection part or of the second connection part provided for electrical contacting in each case overlaps with the molded body. In other words, the semiconductor component has no contact legs which extend out of the molded body in the lateral direction and which are provided for electrically contacting the semiconductor component. The space required for mounting the semiconductor component on a connection carrier, for example a printed circuit board, is thereby reduced.

According to at least one embodiment of the semiconductor component, the first connection part and the second connection part are accessible for external electrical contacting of the semiconductor component at the front side of the semiconductor component and at the rear side of the semiconductor component. The semiconductor component is thus externally electrically contactable from the front side or from the rear side. In particular, the functioning of the semiconductor component is independent of whether the semiconductor component is electrically contacted only on the front side or only on the rear side. In other words, with the semiconductor component mounted on the connection carrier, either the front side or the rear side can face the connection carrier. As a result, the semiconductor component is distinguished in terms of mountability by particularly high flexibility.

In at least one embodiment of the semiconductor component, the semiconductor component has at least one semiconductor chip, a front side and a rear side opposite the front side, a lead frame having a first connection part and a second connection part, and a molded body, wherein the molded body mechanically connects the first connection part and the second connection part to one another and wherein the first connection part and the second connection part do not project or do not project substantially beyond the molded body in a plan view of the front side of the semiconductor component. On the front side and on the rear side of the semiconductor component, the first connection part and the second connection part are accessible for external electrical contacting of the semiconductor component.

Such a semiconductor component combines a low space requirement when mounted on a connection carrier with a low achievable overall height of the semiconductor component and with a particularly high flexibility in mountability.

According to at least one embodiment of the semiconductor component, the molded body and the lead frame terminate flush in places on a side face delimiting the semiconductor component in the lateral direction. The lead frame thus extends in the lateral direction at least in places up to the side face of the semiconductor component but does not project or at least does not project substantially beyond the side face. “Not substantially” means, for example, a deviation of at most 5 μm.

According to at least one embodiment of the semiconductor component, the lead frame extends in a vertical direction extending perpendicularly to the rear side of the semiconductor component at least through 90% of the maximum vertical extent of the molded body. In particular, the lead frame can also extend completely through the molded body in the vertical direction. However, the lead frame need not necessarily extend through the molded body along a straight line extending vertically. Rather, the lead frame can form the front side of the semiconductor component in a partial region and the rear side of the semiconductor component in a partial region laterally spaced therefrom.

According to at least one embodiment of the semiconductor component, the molded body directly adjoins the semiconductor chip in places. In particular, the molded body can also adjoin a connecting line via which the semiconductor chip is electrically conductively connected to one of the connection parts, for example, the second connection part.

The molded body is molded onto the semiconductor chip in particular in places. This means that the molded body follows the outside shape of the semiconductor chip in places. In particular, the molded body is not a prefabricated housing into which the semiconductor chip is placed. Rather, the molded body is only created during the production of the semiconductor component after the semiconductor chip has already been attached to the lead frame.

According to at least one embodiment of the semiconductor component, the first connection part has a first front contact area and a first rear contact area. In particular, the first front contact area and the first rear contact area are electrically conductively connected to one another via the first connection part so that, during operation of the semiconductor component, the first front contact area and the first rear contact area are at the same electrical potential. The first front contact area and the first rear contact area extend, for example, in parallel to one another and are formed by different partial regions of the lead frame, in particular of the first connection part.

Similarly, the second connection part may have a second front contact area and a second rear contact area.

According to at least one embodiment of the semiconductor component, the front contact area and a front side of the molded body are arranged at the same vertical distance or substantially at the same vertical distance from the rear side of the semiconductor component. In other words, the front side of the molded body and the front contact area are at the same level or at least substantially at the same level. Substantially here means, in particular, that the vertical distances differ from one another by at most 10 μm. In particular, the front contact area and the front side of the molded body may terminate flush, apart from slight manufacturing-related deviations.

According to at least one embodiment of the semiconductor component, the semiconductor chip is arranged on the first connection part and is electrically conductively connected to the second connection part via a connecting line. The connecting line is, for example, embedded in the molded body. The molded body can thus serve to protect the connecting line, for example a wire bond connection, from mechanical stress.

According to at least one embodiment of the semiconductor component, the first connection part has a central region on which the semiconductor chip is arranged. For example, the semiconductor chip is attached to the first connection part with a connecting means, for example, a solder or an electrically conductive adhesive.

According to at least one embodiment of the semiconductor component, the first connection part has an extension which extends away from the central region and forms the first front contact area. The extension and the first connection part are in particular designed as one piece.

In particular, the extension may have a bent region of the lead frame between the central region and the first front contact area. By means of the bent region, the lead frame can form the front side of the semiconductor component in places and the rear side of the semiconductor component in places, even if the molded body has a larger vertical extent, i.e., a larger thickness, than the starting material of the lead frame. For example, the lead frame is bent in such a way that the entire vertical extent of the lead frame is at least 1.5 times as large and at most five times as large as the thickness of the lead frame itself.

According to at least one embodiment of the semiconductor component, the first connection part has a contact pin, wherein the contact pin forms the front contact area and the lead frame has a larger vertical extent in the region of the contact pin than in the central region. For example, the vertical extent in the region of the contact pin corresponds to the original vertical extent, that is to say the original thickness of the metal sheet from which the lead frame results. In the central region, material of the original lead frame may be removed, for example by etching. The first connection part can therefore have traces of an etching method in the central region. In this case, the formation of a bent region of the lead frame can be dispensed with.

Further embodiments relate to a method for producing a plurality of semiconductor components.

According to at least one embodiment, the method comprises a step in which a lead frame having a plurality of component regions is provided. When the lead frame is separated later, a lead frame of the semiconductor component results from each component region of the lead frame, in particular having a first connection part and a second connection part.

According to at least one embodiment of the method, the method comprises a step in which at least one semiconductor chip is arranged and in particular attached, for example by means of a connecting means, in each component region of the lead frame.

According to at least one embodiment of the method, the method comprises a step in which the lead frame is encased in a molding compound in order to form a molded body assembly, wherein the lead frame is accessible for external electrical contacting at a front side of the molded body assembly and at a rear side of the molded body assembly opposite the front side. The conductor frame is encased in particular by means of a molding method.

A molding method is generally understood to be a method by which a molding compound can be formed in accordance with a predetermined mold and, if necessary, cured. In particular, the term “molding method” includes molding, film-assisted molding, injection molding, transfer molding and compression molding.

According to at least one embodiment of the method, the method comprises a step in which the molded body assembly is separated into the plurality of semiconductor components. In particular, each semiconductor component has a molded body as part of the molded body assembly, at least one semiconductor chip and a lead frame with a first connection part and a second connection part.

In at least one embodiment of the method, a lead frame having a plurality of component regions is provided, and at least one semiconductor chip is arranged in each component region of the lead frame. The lead frame is encased in a molding compound in order to form a molded body assembly, wherein the lead frame is accessible for external electrical contacting at a front side of the molded body assembly and at a rear side of the molded body assembly opposite the front side. The molded body assembly is separated into the plurality of semiconductor components.

The described method is expediently carried out in the order listed above. In particular, the conductor frame can be encased after the semiconductor chips have already been attached to the lead frame.

When separating the molded body assembly, the lead frame is in particular also severed between adjacent component regions. The separation is carried out, for example, mechanically, for example by means of sawing, chemically, for example by means of etching, or by means of coherent radiation, for example in a laser separation method.

According to at least one embodiment of the method, the lead frame is bent in places prior to encasing the lead frame in the molding compound. In particular, the bending takes place in such a way that first partial regions of the lead frame extend in a first plane and second partial regions of the lead frame extend in a second plane extending in parallel to the first plane and spaced apart from the first plane.

According to at least one embodiment of the method, when the lead frame is encased, the lead frame is introduced into a mold having an upper part and a lower part, wherein the upper part has projections with which the lead frame is pressed against the lower part in places. In particular, a front side of the semiconductor chip can be covered by means of a projection of the upper part so that the front side of the semiconductor chip is not covered by the molding compound at least in places.

According to at least one embodiment of the method, the lower part has further projections with which the lead frame is pressed against the upper part of the mold in places. Regions of the lead frame which directly adjoin the upper part remain free of the molding compound.

According to at least one embodiment of the method, the lead frame has connectors via which the adjacent components are connected to one another. In particular, at least some of the projections and/or of the further projections can press against the connectors. During separation, the connectors can be severed so that the connectors are no longer or only partially present in the completed semiconductor components.

According to at least one embodiment of the method, some of the connectors are designed as cross connectors, wherein the cross connectors extend obliquely, for instance askew, to the rear side of the molded body assembly. In particular, the cross connectors mechanically connect partial regions of the lead frame extending in the first plane with partial regions of the lead frame extending in the second plane to one another.

According to at least one embodiment of the method, the connectors are severed during separation of the molded body assembly. In particular, separation lines along which the separation takes place can also extend in such a way that at least some of the connectors are severed at two spaced-apart places.

The described method is particularly suitable for producing a semiconductor component described above. Features described in connection with the semiconductor component can therefore also be used for the method and vice versa.

### BRIEF DESCRIPTION OF THE DRAWINGS

Further embodiments and expediencies result from the following description of the exemplary embodiments in conjunction with the figures.

The figures show:

FIGS. 1A, 1B and 1C show an exemplary embodiment of a semiconductor component, wherein FIG. 1A shows a plan view with associated side views omitting the molded body, FIG. 1B shows a plan view and an associated side view of the semiconductor component, and FIG. 1C is a sectional view of the semiconductor component along the line AA′ shown in FIG. 1B;

FIGS. 2A and 2B show an exemplary embodiment of a semiconductor component in a schematic plan view and associated side views omitting the molded body in FIG. 2A and in a schematic plan view in FIG. 2B; and

FIGS. 3A to 3F show an exemplary embodiment of a method for producing semiconductor components, wherein FIGS. 3A and 3D show schematic views in a plan view at various stages of the method, FIGS. 3B and 3C illustrate schematic views of a lower part or an upper part of a mold, and FIGS. 3E and 3F are a schematic plan view and a schematic rear view, respectively, of the produced semiconductor component.

In the figures, the same, similar or similarly acting elements are provided with the same reference signs.

The figures are schematic diagrams and therefore not necessarily true to scale. Rather, comparatively small elements and in particular layer thicknesses may be shown exaggeratedly large for clarity.

### DETAILED DESCRIPTION OF ILLUSTRATIVE EMBODIMENTS

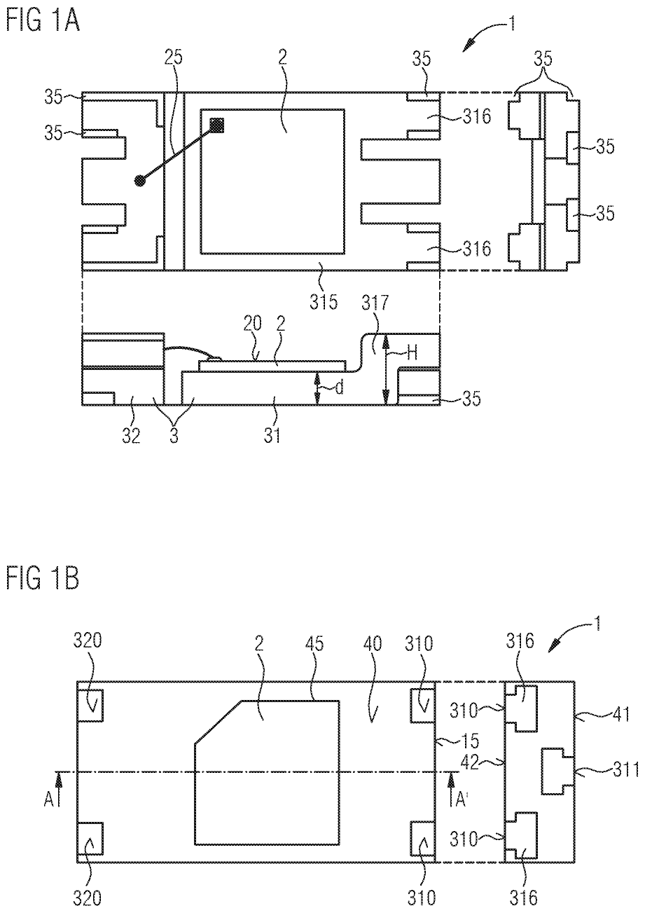

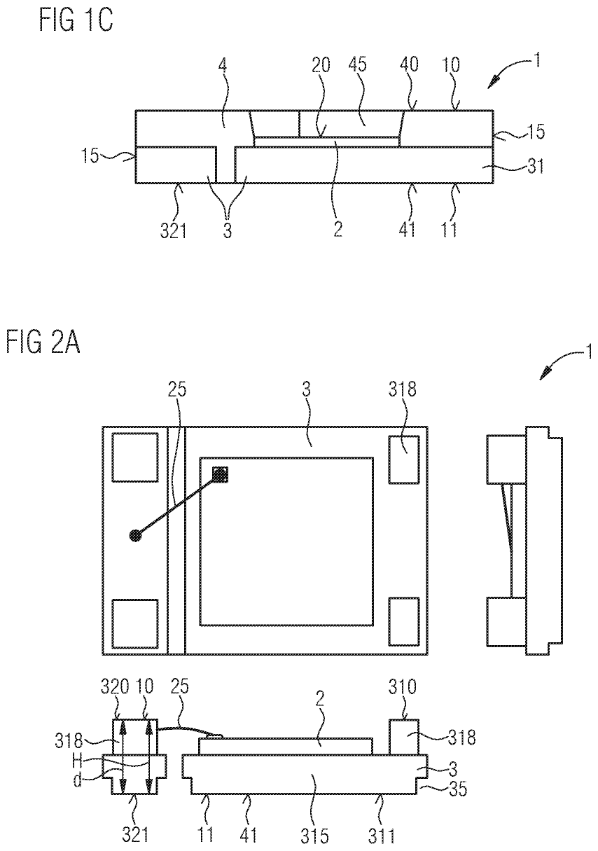

FIGS. 1A to 1C show an exemplary embodiment of a semiconductor component, wherein the molded body of the semiconductor component 1 is not shown in FIG. 1A for improved representation.

The semiconductor component 1 has a semiconductor chip 2, for example an optoelectronic semiconductor chip, which is set up for receiving and/or generating radiation.

The semiconductor component 1 further comprises a lead frame 3 having a first connection part 31 and a second connection part 32. The semiconductor component 1 extends in the vertical direction between a front side 10 and a rear side 11 opposite the front side. In the lateral direction, the semiconductor component 1 is delimited by side faces 15.

The front side, the rear side and the side face of the semiconductor component are each formed in places by the molded body 4 and in places by the lead frame 3. The semiconductor chip 2 is arranged on the first connection part 31. The first connection part 31 does not project beyond the molded body 4 in the plan view of the front side of the semiconductor component. A first front contact area 310 and a first rear contact area 311 are accessible for external electrical contacting of the semiconductor chip 2 at the front side 10 of the semiconductor component and at the rear side 11 of the semiconductor component respectively.

Correspondingly, the second connection part 32 has a second front contact area 320 on the front side 10 and a second rear contact area 321 on the rear side 11 of the semiconductor component 1. The semiconductor chip 2 can be externally electrically contacted either via the first front contact area 310 and the second front contact area 320 or via the first rear contact area 311 and the second rear contact area 321 so that the semiconductor component 1 can be attached to a connection carrier both with the front side 10 and with the rear side 11. Thus, either the front side or the rear side of the semiconductor component may face the connection carrier.

The molded body 4 mechanically stably connects the first connection part 31 and the second connection part 32 to one another. The molded body 4 is furthermore molded onto the semiconductor chip 2 in places. A connecting line 25 via which the semiconductor chip 2 is electrically conductively connected to the second connection part 32 is embedded in the molded body 4. The molded body 4 has a recess 45 in which a front side 20 of the semiconductor chip is exposed.

The first connection part 31 has a central region 315 in which the semiconductor chip 2 is attached to the first connection part. Extending away from the central region 315 is an extension 316, wherein the extension 316 forms the first front contact area 310. Between the first front contact area 310 and the central region 315, the extension 316 has a bent region 317. In the bent region 317, the lead frame 3 does not extend in parallel to the rear side 11 of the semiconductor component 1. By means of the bent region 317, the maximum vertical extent H of the lead frame 3 can be greater than the thickness d of the starting material of the lead frame 3. In the region of the central region 315, the thickness of the lead frame 3 may correspond to the original thickness of the lead frame. For example, the total vertical extent of the lead frame is within the range including 1.5 times and five times the thickness of the lead frame in the region of the central region.

The maximum vertical extent H corresponds to the component height or at least deviates by at most 10% from the component height of the semiconductor component 1. In particular, the lead frame 3 extends in the vertical direction at least through 90% of the maximum vertical extent of the molded body 4 or completely through the molded body.

The front side 40 of the molded body 4 and the lead frame 3 form the front side 10 of the semiconductor component 1 in places. The rear side 41 of the molded body and the lead frame 3, in particular the rear contact areas of the lead frame, form the rear side 11 of the semiconductor component 1.

The lead frame 3, in particular the first connection part 31 and the second connection part 32, have indentations 35 in places. The indentations 35 are filled with the molded body 4 and bring about an improved tooth system between the molded body 4 and the lead frame 3.

At the side faces 15 of the semiconductor component 1, the lead frame 3 and the molded body 4 terminate flush in places.

Of course, the number of the first contact areas and of the second contact areas on the front side and the rear side of the semiconductor component 1 can be varied within wide limits. Furthermore, in a semiconductor component in which the semiconductor chip 2 is not provided for generating or receiving electromagnetic radiation, the recess 45 of the molded body 4 can also be dispensed with so that the semiconductor chip 2 is completely embedded in the molded body 4.

The molded body 4 can be impermeable to the radiation to be generated or received in the semiconductor chip 2. For example, the molded body is designed to be reflective, for example with a reflectivity of at least 55%, or absorbing, for example, with an absorption of at least 55% for impinging radiation.

Expediently, the maximum vertical extent H of the lead frame is at least as large as the sum of the thickness of the lead frame d, thickness of the semiconductor chip 2, including the connecting means with which the semiconductor chip is fixed to the first connection part 31, and the maximum vertical extent of the connecting line 25 so that the connecting line is embedded in the molded body 4. During the production of the semiconductor component, the lead frame 3 can be formed from a flat metal sheet solely by mechanical methods, for example comprising stamping, embossing and/or bending.

A lead frame produced by mechanical methods may be characterized by high planarity and surface quality outside of the bent regions 317. The attachment of the semiconductor chip 2 and the formation of a connecting line in the form of a wire bond connection are thus simplified.

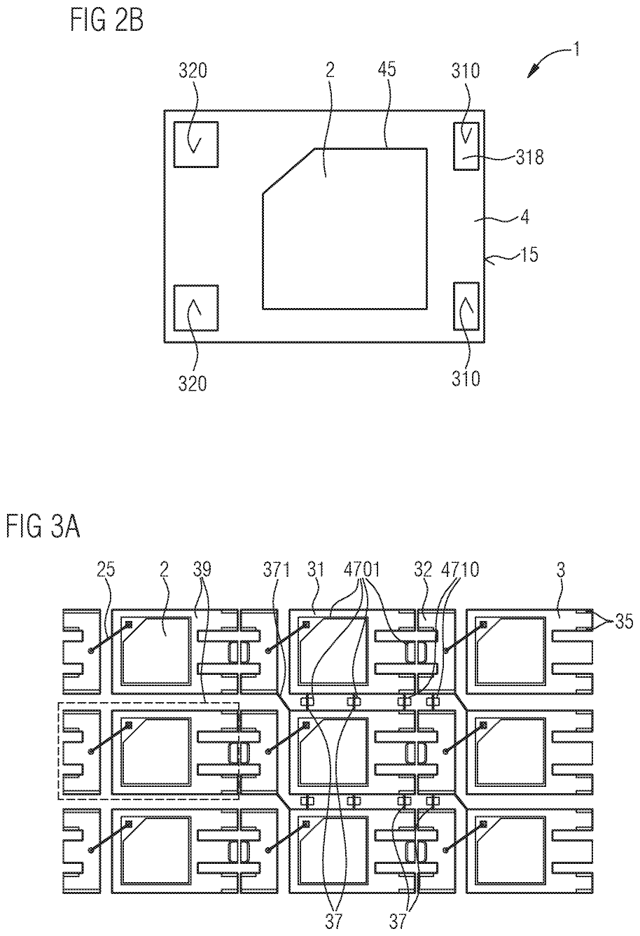

A further exemplary embodiment of a semiconductor component 1 is schematically shown in FIGS. 2A and 2B. This exemplary embodiment substantially corresponds to the exemplary embodiment described in connection with FIGS. 1A to 1C.

In contrast, the first front contact areas 310 and the second front contact areas 320 are each formed by contact pins 318. In the region of the contact pins 318, the lead frame 3 has a larger vertical extent than in the central region 315 in which the semiconductor chip 2 is attached.

In particular, the lead frame 3 can have the original vertical extent of the metal sheet for the lead frame in the region of the contact pins 318. Thus, the thickness d of the lead frame 3 and the maximum vertical extent H of the lead frame are the same.

In the remaining regions of the lead frame 3, in particular in the central region 315, material of the lead frame can be removed, for example, by etching. The lead frame may therefore have etching marks in the central region 315. In this exemplary embodiment, the lead frame may also be formed exclusively by chemical processes. Of course, a combination of mechanical and chemical processes can also be used.

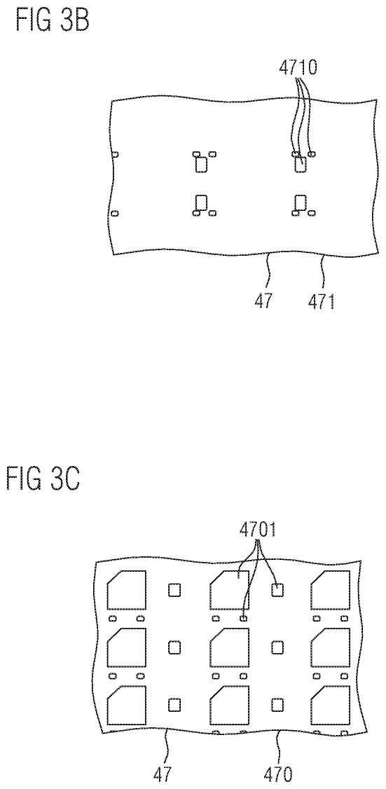

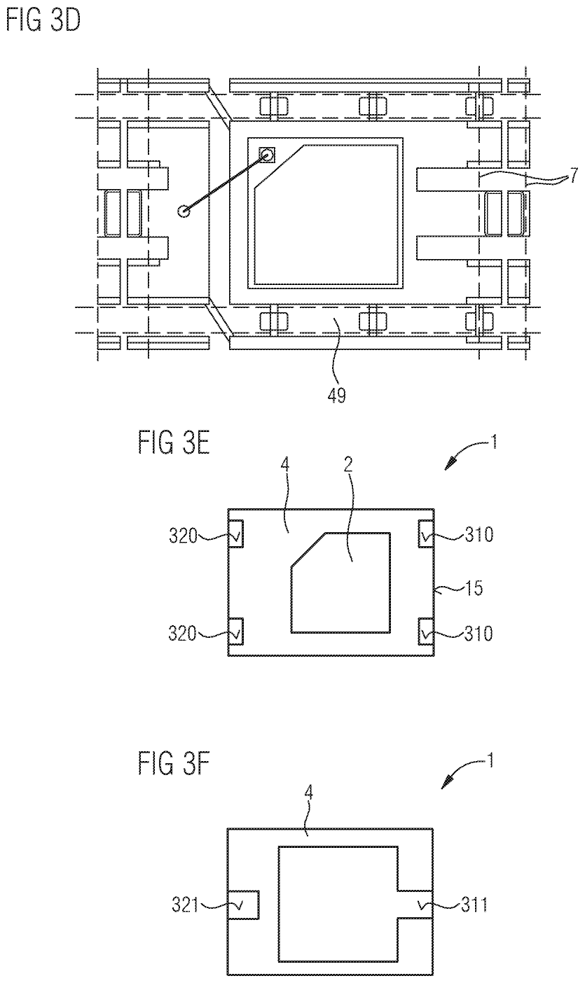

An exemplary embodiment of a method for producing semiconductor components is described with reference to FIGS. 3A to 3F. By way of example, the description is made on the basis of semiconductor components which are designed as described in connection with FIGS. 1A to 1C.

As shown in FIG. 3A, a lead frame 3 is provided, wherein the lead frame 3 has a plurality of component regions 39 arranged side by side in a matrix shape in a lateral direction. A section with 3×3=9 component regions 39 is shown in FIG. 3A. The component regions 39 each have a first connection part 31 and a second connection part 32 of the lead frame, wherein these can be designed as described in connection with FIGS. 1A to 1C.

Adjacent component regions 39 are mechanically connected to one another via connectors 37. Some of the connectors connect component regions that are in the same plane. Cross connectors 371 connect partial regions, located on different planes, of the lead frame 3 to one another. Accordingly, the cross connectors extend obliquely to these planes.

At least some of the projections 4701 and of the further projections 4710 press against the connectors 37. In this way, it can be achieved in a simple manner that the lead frame is pressed against places which are not present in the later semiconductor component.

A semiconductor chip 2 is arranged on the lead frame 3, in particular on the first connection part 31 of each component region 39. The electrically conductive connection to the second connection part 32 takes place via a connecting line 25.

Subsequently, the lead frame is encased in a molding compound in order to form a molded body assembly 49. A molding process is suitable for this purpose.

FIGS. 3B and 3C show section of a lower part 471 and of an upper part 470 of a mold 47 respectively. The upper part 470 has projections 4701. These projections press the lead frame 3 in places against the lower part 471 of the mold. One of the projections 4701 presses against the front side of the semiconductor chip 2 so that the front side of the semiconductor chip 2 is not covered by the molding compound at least in places.

Similarly, the lower part 471 of the mold 47 has further projections 4710 with which the lead frame 3 is pressed against the upper part 470 of the mold 47. At the places at which the lead frame is pressed against the upper part 470, the lead frame 3 remains free of the molding compound. In these regions, the lead frame is accessible for later electrical contacting on the front side of the semiconductor component to be produced.

Subsequently, as shown in FIG. 3D, the molded body assembly 49 can be separated along separation lines 7. As shown in FIG. 3D, more than one separation line, for example two separation lines, may also extend between adjacent component regions 39. As a result, the connectors 37 and in particular also the cross connectors 371 can largely be removed. The side faces of the semiconductor component 15 to be produced are formed during separation and can therefore have characteristic traces of the separation process, such as sawing marks or traces of a chemical material removal or of a material removal by coherent radiation.

FIGS. 3E and 3F each show a separated semiconductor component 1, in a plan view of the front side 10 of the semiconductor component in FIG. 3E and in a plan view of the rear side of the semiconductor component in FIG. 3F.

With the described method, semiconductor components which are distinguished by a compact design both with regard to the space requirement in the lateral direction and with regard to the component height can be produced in a simple and reliable manner.

The invention is not limited by the description based on the exemplary embodiments. Rather, the invention encompasses any novel feature as well as any combination of features, including in particular any combination of features in the claims, even if this feature or combination itself is not explicitly specified in the claims or the exemplary embodiments.

1-18. (canceled)

19. A semiconductor component comprising:
at least one semiconductor chip;
a front side of the semiconductor component and a rear side of the semiconductor component opposite the front side;
a lead frame having a first connection part and a second connection part; and
a molded body mechanically connecting the first connection part and the second connection part to one another,
wherein the first connection part and the second connection part do not project or do not project substantially beyond the molded body in a plan view of the front side, and
wherein the first connection part and the second connection part are respectively accessible for external electrical contacting of the semiconductor component at the front side and at the rear side.

20. The semiconductor component according to claim 19, wherein the molded body and the lead frame terminate flush in places on a side face delimiting the semiconductor component in a lateral direction.

21. The semiconductor component according to claim 19, wherein the lead frame extends at least through 90% of a maximum vertical extent of the molded body in a vertical direction extending perpendicularly to the rear side of the semiconductor component.

22. The semiconductor component according to claim 19, wherein the molded body adjoins the semiconductor chip directly in places.

23. The semiconductor component according to claim 19, wherein the first connection part has a first front contact area and a first rear contact area.

24. The semiconductor component according to claim 23, wherein the first front contact area and a front side of the molded body are arranged at the same vertical distance or substantially at the same vertical distance from the rear side of the semiconductor component.

25. The semiconductor component according to claim 19, wherein the semiconductor chip is arranged on the first connection part and is electrically conductively connected to the second connection part via a connecting line, and wherein the connecting line is embedded in the molded body.

26. The semiconductor component according to claim 19, wherein the first connection part has a central region on which the semiconductor chip is arranged, and wherein an extension extending away from the central region forms a first front contact area.

27. The semiconductor component according to claim 26, wherein the extension has a bent region of the lead frame between the central region and the first front contact area.

28. The semiconductor component according to claim 19, wherein the first connection part has a central region, on which semiconductor chip is arranged, and a contact pin, wherein the contact pin forms a front contact area and the lead frame has a larger vertical extent in a region of the contact pin than in the central region.

29. A method for producing a plurality of semiconductor components, the method comprising:
providing a lead frame having a plurality of component regions;
arranging at least one semiconductor chip in each component region of the lead frame;
encasing the lead frame in a molding compound in order to form a molded body assembly,
wherein the lead frame is accessible for external electrical contacting at a front side of the molded body assembly and at a rear side of the molded body assembly opposite the front side; and
separating the molded body assembly into the plurality of semiconductor components.

30. The method according to claim 29, further comprising bending the lead frame before encasing the lead frame.

31. The method according to claim 29, wherein encasing the lead frame comprises introducing the lead frame into a mold having an upper part and a lower part, and wherein the upper part has projections with which the lead frame is pressed against the lower part in places.

32. The method according to claim 31, wherein the lower part has further projections with which the lead frame is pressed against the upper part in places.

33. The method according to claim 29, wherein the lead frame has connectors via which adjacent component regions are connected to one another, and wherein at least some of the projections press against the connectors.

34. The method according to claim 33, wherein some of the connectors are designed as cross connectors which extend obliquely to the rear side of the molded body assembly.

35. The method according to claim 33, wherein separating the molded body assembly comprises severing the connectors.

36. A semiconductor component, wherein the semiconductor component is one of the semiconductor components produced according to claim 29.

37. A semiconductor component comprising:
at least one semiconductor chip;
a front side of the semiconductor component and a rear side of the semiconductor component opposite the front side;
a lead frame having a first connection part and a second connection part: and
a molded body mechanically connecting the first connection part and the second connection part to one another,
wherein the first connection part and the second connection part do not project or do not project substantially beyond the molded body in a plan view of the front side,
wherein the first connection part and the second connection part are respectively accessible for external electrical contacting of the semiconductor component at the front side and at the rear side,
wherein the molded body adjoins the semiconductor chip directly in places, and
wherein the molded body is reflective or absorbing.
